(19) United States
(12) Patent Application Publication
(10) Pub. No.: US 2026/0247897 A1
(43) Pub. Date: Aug. 20, 2026

(54) SYSTEM FOR TRANSFERRING SUBSTRATE AND APPARATUS FOR FABRICATING SEMICONDUCTOR DEVICE

(71) Applicant: Samsung Electronics Co., Ltd., Suwon-si (KR)

(72) Inventors: Pyeonggyu SONG, Suwon-si (KR); Hyunjoo JEON, Suwon-si (KR)

(21) Appl. No.: 19/299,599

(22) Filed: Aug. 14, 2025

(30) Foreign Application Priority Data
Feb. 20, 2025 (KR) 10-2025-0022236

(51) Int. Cl. H10P 72/00; B25J 11/00

(52) U.S. Cl. CPC H10P 72/0402; B25J 11/0095

(57) ABSTRACT

A transfer system includes a load port receiving a container accommodating a substrate, an enclosure disposed between the load port and a process equipment that performs a semiconductor device manufacturing process on the substrate, wherein the load port, the enclosure, and the process equipment are arranged in a first direction, a first fan disposed on an upper wall of the enclosure and configured to generate an airflow inside the enclosure flowing from the first fan toward a lower wall of the enclosure, and a first airflow guide disposed on a front wall of the enclosure adjacent to the load port and configured to direct a first portion of the airflow along a first path, and change a flow path of the first portion of the airflow directed along the first path to a second path which is closer, in the first direction, to an inner surface of the front wall.

### CROSS-REFERENCE TO RELATED APPLICATION

This application claims priority to Korean Patent Application No. 10-2025-0022236, filed in the Korean Intellectual Property Office on Feb. 20, 2025, the entire contents of which are hereby incorporated by reference.

### BACKGROUND

### Field

The present disclosure relates to a substrate transfer system including a gas guide and a semiconductor device manufacturing apparatus.

### Description of Related Art

In semiconductor manufacturing processes, an EFEM (equipment front end module) and a FOUP (front opening unified pod) are used as devices that maximize wafer handling and transfer efficiency.

The EFEM is installed at the front of a semiconductor manufacturing apparatus, and may load and unload wafers from a FOUP, which stores and transfers a plurality of wafers in a safe manner. In this case, precise process control and fine mechanical operations are desirable to prevent contamination and damage to the wafers, and interface technology is important for smooth linkage between pieces of equipment.

### DESCRIPTION OF THE INVENTION

### Problems to be Solved

The present disclosure relates to a substrate transfer system and a semiconductor device manufacturing apparatus, which prevent contamination and damage to a substrate by blocking or limiting outside air inflow into a container that accommodates a plurality of substrates, as well as preventing outflow of gas from the container.

The problems to be solved by the present disclosure are not limited to those described above, and other problems not mentioned will be clearly understood by those of ordinary skill in the art from the following description of the invention.

### SUMMARY

According to an aspect of the present disclosure, a transfer system includes a load port configured to receive a container accommodating a substrate, an enclosure disposed between the load port and a process equipment that performs a semiconductor device manufacturing process on the substrate, wherein the load port, the enclosure, and the process equipment are arranged in a first direction, a first fan disposed on an upper wall of the enclosure and configured to generate an airflow inside the enclosure flowing from the first fan toward a lower wall of the enclosure, and a first airflow guide disposed on a front wall of the enclosure adjacent to the load port and configured to direct a first portion of the airflow along a first path, and change a flow path of the first portion of the airflow directed along the first path to a second path which is closer, in the first direction, to an inner surface of the front wall of the enclosure.

According to an aspect of the present disclosure, a transfer system includes a load port on which a container accommodating a substrate is positioned, an enclosure disposed between the load port and a process equipment that performs a semiconductor device manufacturing process on the substrate, wherein the load port, the enclosure, and the process equipment are arranged in a first direction, a fan disposed on an upper wall of the enclosure and configured to generate an airflow inside the enclosure flowing from the fan toward a lower wall of the enclosure, an exhaust portion connected to the lower wall of the enclosure and exhausting the airflow inside the enclosure, a filter disposed below the fan and configured to filter contaminants from air introduced into an inside of the enclosure, and a first airflow guide disposed on a front wall of the enclosure adjacent to the load port. The first airflow guide comprises a bracket coupled to the front wall of the enclosure, a duct coupled to the bracket, extending in a second direction perpendicular to the first direction and parallel to an inner surface of the front wall of the enclosure, the duct having a plurality of inflow slots opened toward the upper wall of the enclosure, through which a first portion of the airflow generated from the fan is introduced along a first path, and a plurality of inflow passages configured to deliver the first portion of the airflow, and a discharge portion coupled to the bracket and connected to a lower end of the duct, the discharge portion receiving the first portion of the airflow from the plurality of inflow passages via a plurality of discharge passages, changing a flow direction of the first portion of gas, and extending in the second direction, the discharge portion having a plurality of discharge slots opened toward the lower wall of the enclosure so as to discharge the first portion of the airflow along a second path directed more toward a door of the container than the first path in the first direction.

According to an aspect of the present disclosure, a semiconductor device manufacturing apparatus includes a load port on which a container accommodating a substrate is positioned, a process equipment configured to perform a semiconductor device manufacturing process on the substrate, an enclosure disposed between the load port and the process equipment, a transfer robot installed inside the enclosure and configured to transfer the substrate between the load port and the process equipment, a controller configured to control the transfer robot, a fan disposed on an upper wall of the enclosure and configured to generate an airflow flowing from the fan toward a lower wall of the enclosure, and an airflow guide disposed on a front wall of the enclosure adjacent to the load port. A portion of the airflow generated from the fan is introduced into the airflow guide through a first path. The airflow guide is configured to discharge the portion of the airflow along a second path directed more toward a door of the container than the first path.

According to various embodiments of the present disclosure, the gas guide may function to block or limit a path through which external air flows into the container in which the substrate is accommodated, and to induce dry gas supplied into the container to stay inside the container so that humidity inside the container may be suppressed from rising.

According to various embodiments of the present disclosure, the container accommodating the substrate may remain relatively dry, and the risk of moisture forming on the substrate surface or particles being adsorbed onto the substrate may be reduced.

According to various embodiments of the present disclosure, airflow interference between the container accommodating the substrate and the outside may be reduced, and the internal process environment may become even more stabilized.

According to various embodiments of the present disclosure, contamination of the substrate may be prevented and/or removed when the substrate is transferred to the process facility.

The numerous beneficial advantages and effects of the present disclosure are not limited to the above, and will be more clearly understood in the course of explaining specific embodiments of the present disclosure.

### BRIEF DESCRIPTION OF THE DRAWINGS

FIG. 1 illustrates a plan view of a transfer system according to embodiments of the present disclosure.

FIG. 2 is a cross-sectional view illustrating a semiconductor device manufacturing apparatus according to embodiments of the present disclosure.

FIG. 3 illustrates a diagram for explaining a semiconductor device manufacturing method using the semiconductor device manufacturing apparatus according to embodiments of the present disclosure.

FIG. 4 illustrates a flowchart for explaining the semiconductor device manufacturing method according to embodiments of the present disclosure.

FIGS. 5 and 6 illustrate diagrams for explaining a detailed structure of the container shown in FIGS. 2 and 3.

FIG. 7 illustrates a diagram showing a process of installing a gas guide of FIGS. 2 and 3.

FIG. 8 is a partial cross-sectional view illustrating the detailed structure of the gas guide shown in FIGS. 2 and 3.

FIGS. 9, 10, and 11 are cross-sectional views illustrating modified examples of the gas guide according to various embodiments of the present disclosure.

FIGS. 12 and 13 illustrate diagrams showing examples in which one or more fans are disposed in the gas guide.

FIGS. 14 through 16 illustrate diagrams showing examples in which a second gas guide is further provided according to various embodiments of the present disclosure.

FIG. 17 illustrates data comparing relative humidity inside the container depending on whether the gas guide is installed.

FIG. 18 illustrates the degree of defects on a substrate depending on whether the gas guide is installed.

### DETAILED DESCRIPTION

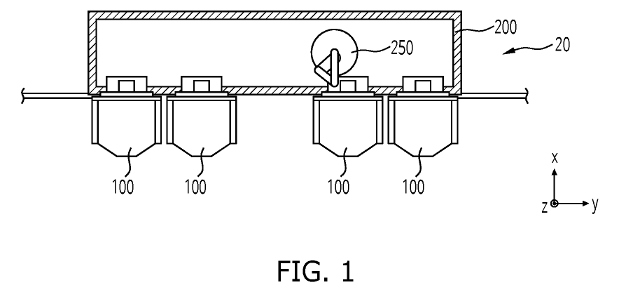

Hereinafter, various embodiments of the present disclosure will be described with reference to FIGS. 1 to 18. Throughout the entire specification, the same reference numerals may denote the same components.

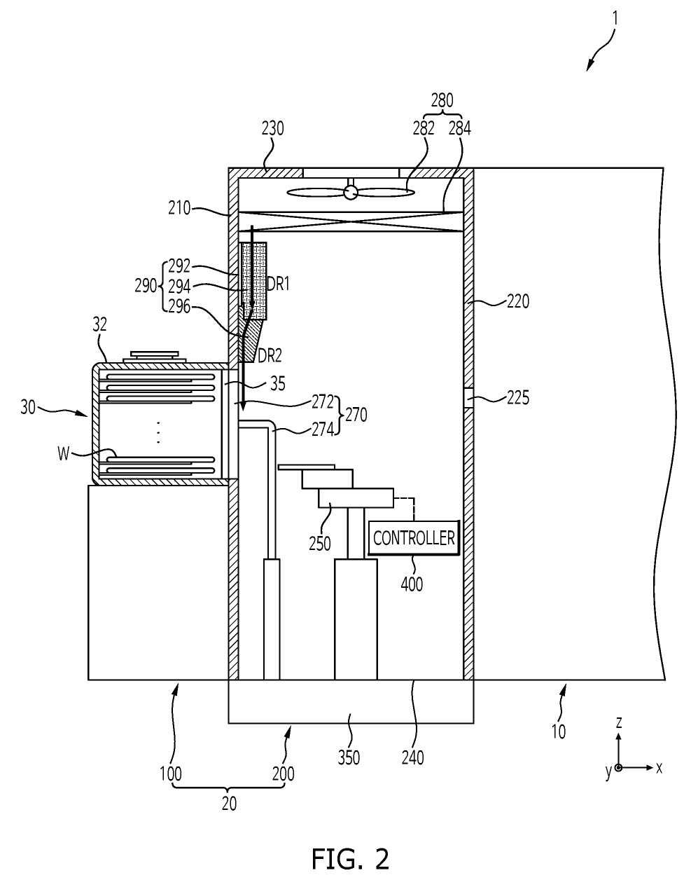

FIG. 1 is a plan view of a transfer system 20 according to embodiments of the present disclosure, and FIG. 2 is a cross-sectional view illustrating a semiconductor device manufacturing apparatus 1 according to embodiments of the present disclosure.

The semiconductor device manufacturing apparatus 1 may include a process facility 10 (i.e., a process equipment) and a transfer system 20.

The process facility 10 may perform at least part of a semiconductor device manufacturing process. The process facility 10 may include a load lock chamber and a process chamber. The process chamber may be a chamber for performing at least part of a semiconductor device manufacturing process such as a chemical vapor deposition process, a photolithography process, and an etching process.

The transfer system 20 may be disposed in front of the process facility 10. The transfer system 20 may include a load port 100 on which a container 30 is placed, a frame 200 (i.e., an enclosure or a housing), a transfer robot 250, a door opener 270, a fan filter unit 280, and a gas guide 290 (i.e., an airflow guide). The transfer system 20 is not limited thereto, and some components may be omitted, or additional components may be included.

The transfer system 20 may be, for example, an equipment front end module (EFEM). The inside of the frame 200 may be configured to maintain a high degree of cleanliness (for example, a low-particle environment).

The load port 100 may be coupled to the front of the frame 200, and may be disposed at the front of the frame 200. One or more load ports 100 may be arranged. Referring to FIG. 1, although the transfer system 20 is shown to include four load ports 100, it is not limited thereto. In an embodiment, the load port 100, the frame 200, and the process facility 10 may be arranged in a first direction (e.g., an x direction) parallel to a floor on which the load port 100, the frame 200, and the process facility 10 are installed.

The load port 100 may have a flat upper surface. A container 30 accommodating a substrate W may be placed on the load port 100.

The container 30 placed on the load port 100 may include a main body 32 having a space for accommodating a substrate W (for example, a wafer), and a door 35 that opens and closes the container 30. The main body 32 of the container 30 may have a groove (or slot) on its inner wall into which part of the edge of the substrate W may be inserted. The container 30 may be sealed by the door 35 so that outside gas does not flow in during movement. For example, the container 30 may be a front opening unified pod (FOUP).

The frame 200 may be disposed between the process facility 10 and the load port 100. The frame 200 may have a rectangular parallelepiped shape, but is not limited thereto. One or more transfer robots 250 may be arranged/installed in the inside of the frame 200 for transferring the substrate W between the container 30 on the load port 100 and the process facility 10.

A front face 210 (i.e., a front wall) of the frame 200 adjacent to the load port 100 may have an opening serving as a path through which the substrate W is transferred between the container 30 and the frame 200. A door opener 270 for opening and closing the door 35 of the container 30 may be disposed inside the frame 200. The door opener 270 may include a door holder 272 and an arm 274. The door holder 272 may be coupled to the door 35 of the container 30 and separate the door 35 from the container 30, and the arm 274 may move the door holder 272 up and down.

A rear face 220 (i.e., a rear wall) of the frame 200, which faces the front face 210 of the frame 200 and adjacent to the process facility 10, may include an opening 225 formed therein that serves as a path through which the substrate W is transferred between the frame 200 and the process facility 10.

A fan filter unit 280 for maintaining a high degree of cleanliness in the inside of the frame 200 may be disposed on an upper surface 230 (i.e., an upper wall) of the frame 200. The fan filter unit 280 may include a blowing fan 282 and a filter 284.

The blowing fan 282 of the fan filter unit 280 may be disposed on the upper surface 230 of the frame 200, and may blow gas from outside and/or inside the frame 200 in a downward direction (for example, in a -z direction) within the frame 200. For example, the blowing fan 282 may generate an airflow inside the frame 200 from the blowing fan 282 toward a lower surface 240 (i.e., a lower wall) of the frame 200. In an embodiment, the downward direction may be perpendicular to the floor. The blowing fan 282 may rotate by a motor (not shown). Without limitation, additional or alternative blowing means, such as a blower, a compressor, a venturi system, and an air jet nozzle, for blowing gas from outside and/or inside the frame 200 in a downward direction (for example, in a -z direction) within the frame 200 may be used in addition to or instead of the blowing fan 282.

The filter 284 of the fan filter unit 280 may be disposed below the blowing fan 282 and may filter contaminants from air introduced into the inside of the frame 200.

An exhaust portion 350, through which gas in the frame 200 is exhausted, may be formed or disposed on a lower surface 240 (i.e., a lower wall) of the frame 200. For example, gas introduced into the frame 200 from outside by the fan filter unit 280 may be exhausted through the exhaust portion 350. In an embodiment, an upper surface of the exhaust portion 350 may serve as the lower surface 240 of the frame 200. In an embodiment, a plurality of holes may be formed at the lower surface 240 for exhaustion. The gas introduced into the frame may be delivered to the exhaust portion 350 through the plurality of holes. In an embodiment, the exhaust portion 350 may be part of the frame 200.

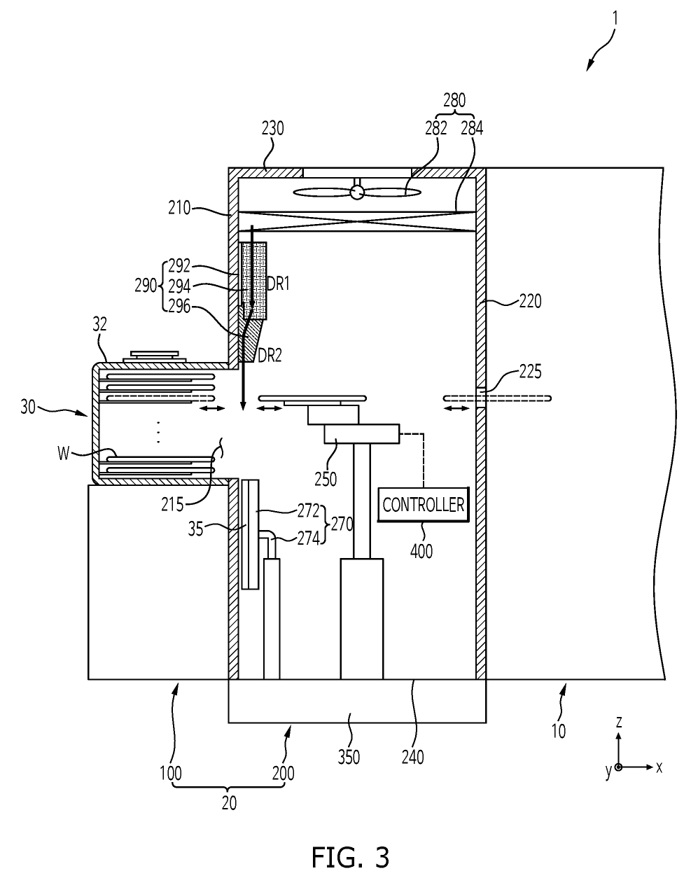

A gas guide 290 (i.e., an airflow guide) may be disposed on the front face 210 of the frame 200 adjacent to the load port 100. A first portion of the gas blown from the blowing fan 282 may flow into the gas guide 290 along a first path DR1, and the gas guide 290 may discharge the introduced gas along a second path DR2 directed more toward the door 35 of the container 30 than the first path DR1. In an embodiment, the second path DR2 may be closer to the front face 210 (i.e., an inner surface of the front wall of the enclosure) in the first direction than the first path DR1, thereby the downward airflow discharging from the gas guide 290 serving to cover an opening 215 of the container 30, which will be described with reference to FIG. 3. In other words, the downward airflow discharging from the gas guide 290 may serve as an air curtain for the opening 215.

In an embodiment, the gas guide 290 may include a bracket 292, a duct 294, and a discharge portion 296. The bracket 292 may fix and/or support the duct 294 and the discharge portion 296 at predetermined positions. A portion of the gas blown from the blowing fan 282 may be introduced into the duct 294 via the first path DR1 of the gas guide 290, and the discharge portion 296 may receive the portion of the gas blown from the blowing fan 282 via the duct 294 and guide it to discharge along the second path DR2. The gas guide 290 may function to block or limit an inflow path of outside gas into the inside of the container 30, and to induce the dry gas supplied to the inside of the container 30 to remain therein so as to suppress an increase in humidity inside the container 30. As a result, the inside of the container 30 may remain relatively dry, reducing the risk of moisture forming on the substrate surface or of particles being adsorbed thereon. In addition, the interference of airflow with the outside may be reduced, thereby stabilizing the internal process environment even further.

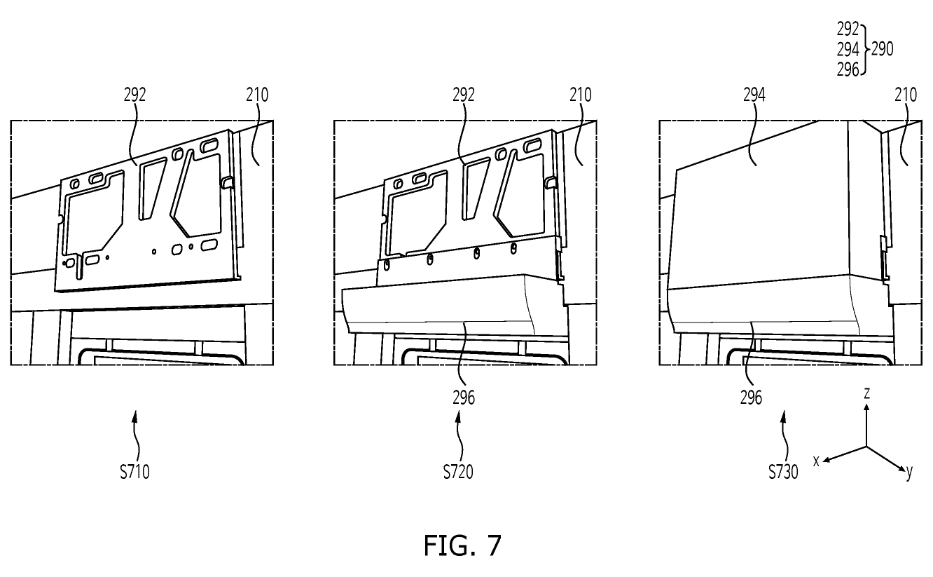

The detailed structure of the gas guide 290 and the technical effects thereof according to various embodiments will be described in detail below with reference to FIGS. 7 to 18.

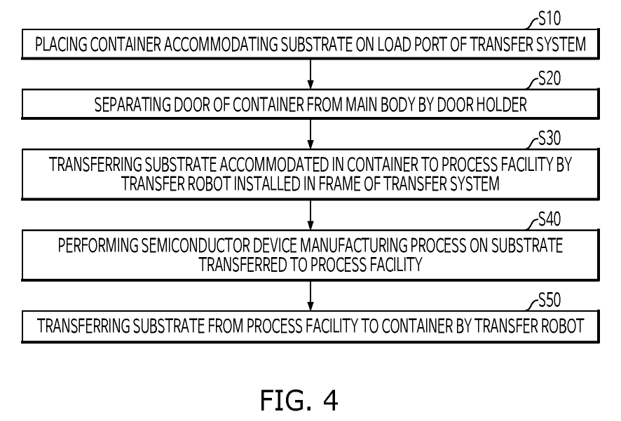

FIG. 3 is a diagram for explaining a semiconductor device manufacturing method using the semiconductor device manufacturing apparatus 1 according to embodiments of the present disclosure, and FIG. 4 is a flowchart for explaining the semiconductor device manufacturing method according to embodiments of the present disclosure.

A semiconductor device manufacturing method according to embodiments of the present disclosure will now be described with reference to FIGS. 3 and 4.

A container 30 accommodating a substrate W may be placed on the load port 100 of the transfer system 20 by a transfer device (not shown) (S10). The transfer device that transfers the container 30 accommodating the substrate W may be an overhead transfer, an overhead conveyor, or an automatic guided vehicle.

A door 35 of the container, which is coupled to the main body 32, may be separated from the main body 32 by the door holder 272 (S20). The door holder 272 coupled to the door 35 of the container may be moved downward by the arm 274, and the space inside the main body 32 may communicate with the space inside the frame 200 through an opening 215.

Once the door 35 of the container is separated from the main body 32, the transfer robot 250 operates, and the substrate W accommodated in the container may be transferred to the process facility 10 by the transfer robot 250 installed in the frame 200 of the transfer system 20 (S30).

At least part of a semiconductor device manufacturing process may be performed on the substrate W transferred to the process facility 10 (S40). The semiconductor device manufacturing process may include a chemical vapor deposition process, a photolithography process, and an etching process, and may be performed in a process chamber within the process facility 10.

When the semiconductor device manufacturing process is completed, the substrate W may be transferred from the process facility 10 back to the container 30 by the transfer robot 250 (S50). The arm 274 may move the door holder 272, which is coupled to the separated door 35, toward the upper surface 230 of the frame 200. The door holder 272 may couple the door 35 with the main body 32, and the door holder 272 may be separated from the door 35 so that the container 30 is closed (for example, sealed).

The above-described operations of the transfer robot 250 and the door opener 270 may be controlled by the controller 400. In the present disclosure, the controller 400 is shown disposed in the frame 200, but is not limited thereto, and may be arranged in any location able to control the transfer robot 250 and the door opener 270 through wired or wireless communication.

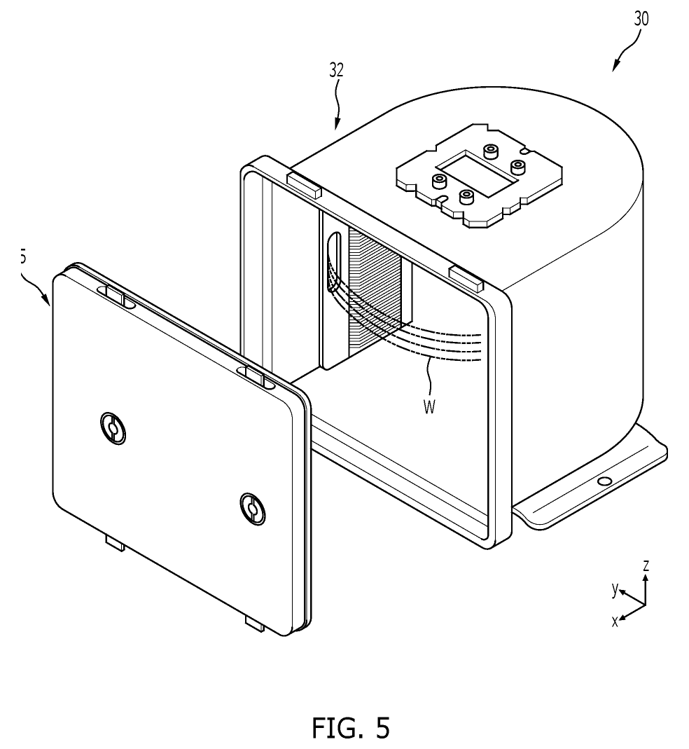

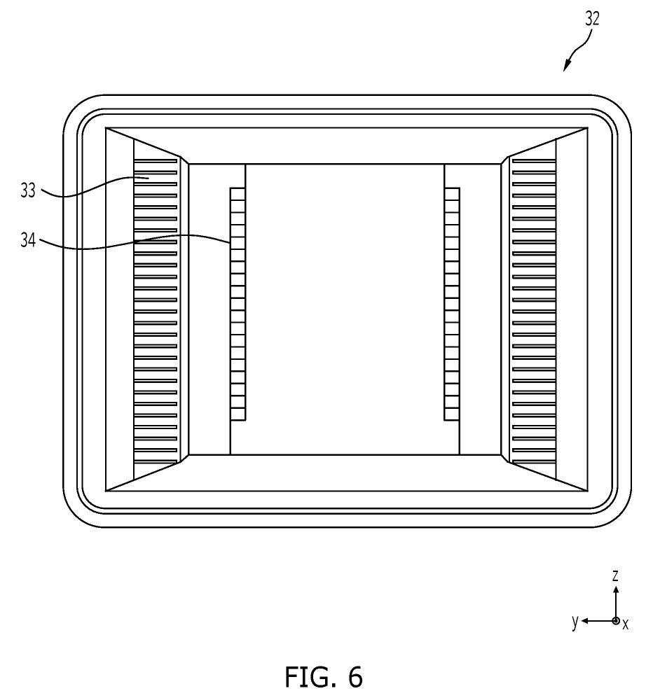

FIGS. 5 and 6 are diagrams for explaining a detailed structure of the container 30 shown in FIGS. 2 and 3. FIG. 5 is a perspective view of the container 30, and FIG. 6 is a plan view viewed from an opening of the container 30.

Referring to FIGS. 5 and 6, the container 30 may include a main body 32 that accommodates substrates W and has one open surface, and a door 35 for sealing the main body 32.

Referring to FIG. 6, a groove 33 into which part of the edge of the substrate W may be inserted may be formed on an inner sidewall of the main body 32.

Referring to FIG. 6, a gas nozzle 34 may be disposed on an inner sidewall of the main body 32. The gas nozzle 34 may inject gas (for example, nitrogen gas) supplied from outside of the container 30 into the inside of the container 30. The gas supplied to the gas nozzle 34 from outside of the container 30 may be a low-humidity gas. In this way, a low-humidity environment may be created inside the container 30, and process defects of the substrate W may be reduced. Although the gas nozzle 34 is shown disposed on a side surface inside the main body 32, it is not limited thereto.

Referring to FIGS. 3 and 6, if the gas guide 290 is not disposed inside the frame 200, a complex vortex may occur in an upper area of the opening 215 due to interaction between the downward airflow generated by the blowing fan 282 and the gas injected from the gas nozzle 34 when the container 30 is opened. If turbulence or vortex flows occur in the opening 215, external particles or contaminants may more easily flow in. In addition, a lower area of the opening 215 may be directly exposed to the gas in the frame 200, which may have a relatively higher humidity, and that gas may flow into the container 30, causing the humidity inside the container 30 to increase. As a result, moisture condensation on the substrate surface, among other factors, may cause the defect rate of the substrate to rise. To address these issues, as shown in FIGS. 2 and 3, the gas guide 290 may be disposed inside the frame 200, and the detailed structure of the gas guide 290 will be described in detail below with reference to FIGS. 7 to 16.

FIG. 7 illustrates a diagram showing a process of installing the gas guide 290 of FIGS. 2 and 3, and FIG. 8 is a partial cross-sectional view illustrating the detailed structure of the gas guide 290 of FIGS. 2 and 3.

Referring to FIGS. 2, 3, and 7, the bracket 292 may be coupled to the front face 210 of the frame (S710). The bracket 292 may be formed and arranged to support the duct 294 and the discharge portion 296. For example, the bracket 292 may be fixed at a specific location on the front face 210 of the frame. By installing the bracket 292, the positions where the duct 294 and the discharge portion 296 will be coupled become clearly defined, and the relative positional alignment between the duct 294 and the discharge portion 296 may be facilitated. Such structural features of the bracket 292 may simplify the installation process of the gas guide 290.

Next, the bracket 292 and the discharge portion 296 may be coupled (S720). The discharge portion 296 extends from a lower end of the duct 294. That is, the discharge portion 296 may be connected to the duct 294 at a lower end of the duct 294. As such, the discharge portion 296 may guide and discharge a portion of the gas received from the duct 294 toward the door (for example, 35 in FIGS. 2 and 3) of the container (for example, 30 in FIGS. 2 and 3) that accommodates the substrate.

The duct 294 may be coupled to the bracket 292 at an upper part of the discharge portion 296 (S730). An upper surface of the discharge portion 296 may support a lower surface of the duct 294. The duct 294 may be supported on the front face 210 of the frame through the bracket 292 and may serve as a path for gas inflow.

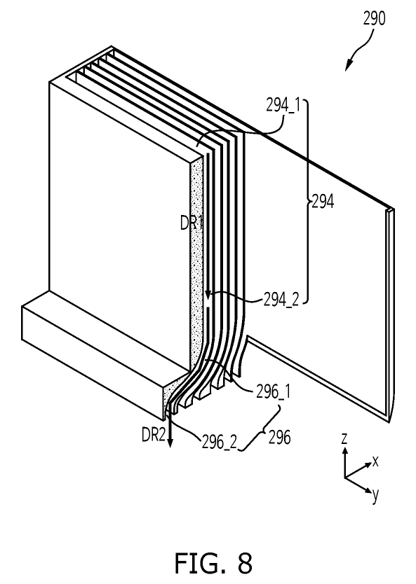

Referring to FIG. 8, the duct 294 may have a plurality of inflow slots 294_1, and a plurality of inflow passages 294_2 that are formed to connect the plurality of inflow slots 294_1 to a plurality of discharge passages 296_1. In an embodiment, the plurality of inflow slots 294_1 may have a plurality of inflow openings positioned at an upper surface of the gas guide 290. Each of the plurality of inflow slots 294_1 may extend in a second direction (for example, the y direction) and may be open toward an upper portion of the frame 200. The second direction is parallel to the floor and perpendicular to the first direction and the downward direction.

Through the plurality of inflow slots 294_1, gas introduced into the inside of the duct 294 along the first path DR1 can be transferred to the discharge portion 296 through the plurality of inflow passages 294_2. As a result, the gas can be guided in a uniform flow by the duct 294, allowing the flow rate and flow direction of the gas to be stably maintained while being conveyed to the discharge portion 296.

The discharge portion 296 may have the plurality of discharge passages 296_1 that change the flow direction of the gas toward a plurality of discharge slots 296_2, and the plurality of discharge slots 296_2. In an embodiment, the plurality of discharge slots 296_2 may have a plurality of discharge openings positioned at a lower surface of the gas guide 290. Each of the plurality of discharge slots 296_2 may extend in the second direction (for example, the y direction) parallel to the front face 210 of the frame 200 and may be open toward a lower portion of the frame 200. Gas may be discharged along the second path DR2 through the plurality of discharge slots 296_2.

Through this arrangement, after the gas is introduced into the inside of the duct 294, it flows along multiple paths and is guided by the discharge portion 296 to an area adjacent to the door of the container accommodating the substrate. This combination of the duct 294, the discharge portion 296, and the bracket 292 that supports them may enhance gas transfer efficiency and help control contamination inside the container and prevent an increase in humidity caused by the influx of external air.

In an embodiment, the total area of the plurality of discharge slots 296_2 may be smaller than the total area of the plurality of inflow slots 294_1. Thus, the gas passing through the duct 294 may be accelerated in the discharge portion 296, and as the flow velocity of the gas increases, backflow of outside air into the container accommodating the substrate may be suppressed.

In an embodiment, among the areas of the plurality of discharge slots 296_2, the discharge slot closest to the container door may have the largest area. For example, in FIG. 8, the discharge slot that is farthest in the -x direction may have the largest area. In this way, gas may be more intensively discharged in the area adjacent to the door. As a result, intrusion of outside air or contaminants into the container accommodating the substrate may be effectively suppressed, and the environment inside the container may be more stably maintained.

Although the duct 294 and the discharge portion 296 are shown as separate components in FIGS. 7 and 8, they are not limited thereto. For example, the duct 294 and the discharge portion 296 may be formed as an integral unit.

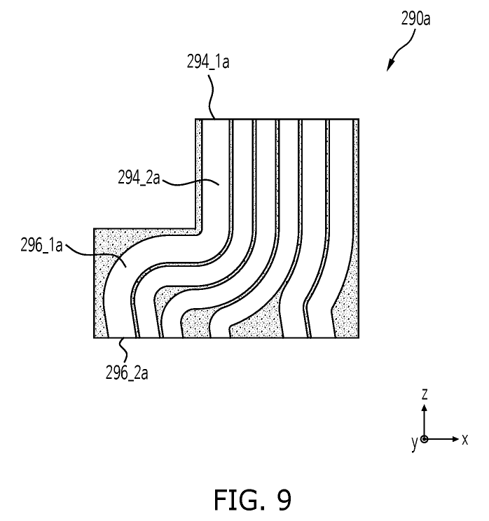

FIGS. 9, 10, and 11 are cross-sectional views illustrating modified examples of the gas guide according to various embodiments of the present disclosure.

The inflow slots 294_1a, 294_1b, and 294_1c and the inflow passages 294_2a, 294_2b, and 294_2c in FIGS. 9 to 11 may be formed to extend so that gas moves in a vertical direction (for example, a -z direction). The discharge passages 296_1a, 296_1b, and 296_1c and the discharge slots 296_2a, 296_2b, and 296_2c in FIGS. 9 to 11 may have curvatures set (i.e., may be curved or bent) so that gas is intensively injected toward the door of the container in which the substrate is accommodated. In this way, gas may be uniformly supplied, and the possibility of external air or contaminants flowing in may be further reduced.

Referring to FIG. 9, the gas guide 290a may be formed so that the plurality of inflow slots 294_1a and the plurality of inflow passages 294_2a have relatively short paths. In the gas guide 290a of FIG. 9, the cross-sectional areas of each of the plurality of inflow slots 294_1a, the plurality of inflow passages 294_2a, the plurality of discharge passages 296_1a, and the plurality of discharge slots 296_2a may be formed relatively large.

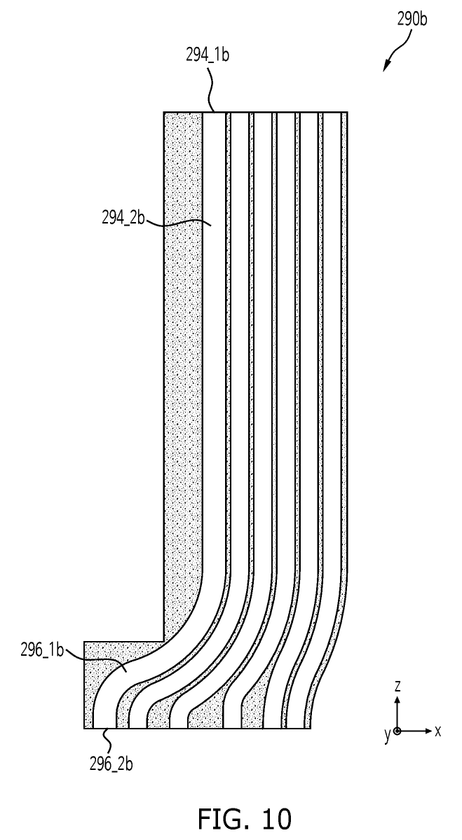

Referring to FIG. 10, the gas guide 290b may be formed so that the plurality of inflow slots 294_1b and the plurality of inflow passages 294_2b extend longer in the vertical direction (for example, the z direction) compared to the gas guide 290a of FIG. 9. Because the plurality of inflow slots 294_1b and the plurality of inflow passages 294_2b are formed longer, the gas may be sufficiently diffused inside the duct 294, pressure drop may be moderated, and a stable flow may be obtained. In the gas guide 290b of FIG. 10, the cross-sectional areas of each of the plurality of inflow slots 294_1b, the plurality of inflow passages 294_2b, the plurality of discharge passages 296_1b, and the plurality of discharge slots 296_2b may be formed relatively smaller compared to those in FIG. 9, thereby inducing gas to be intensively discharged at the lower end.

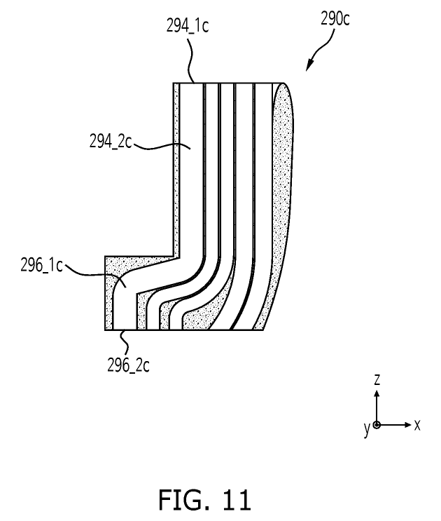

Referring to FIG. 11, in the gas guide 290c, the plurality of inflow slots 294_1c and the plurality of inflow passages 294_2c may have moderate lengths and cross-sectional areas, as compared to the gas guides 290a and 290b in FIGS. 9 and 10.

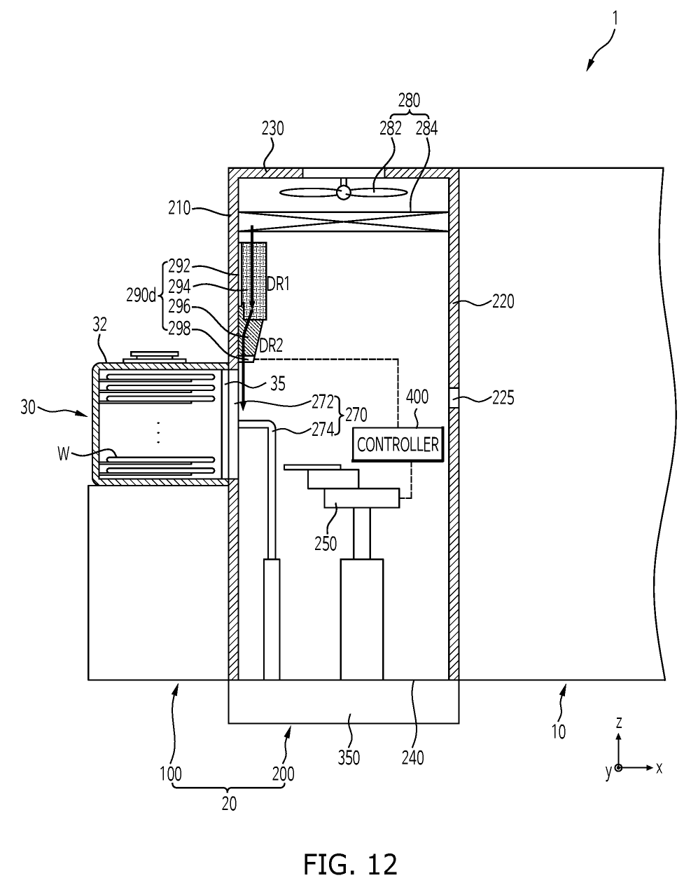

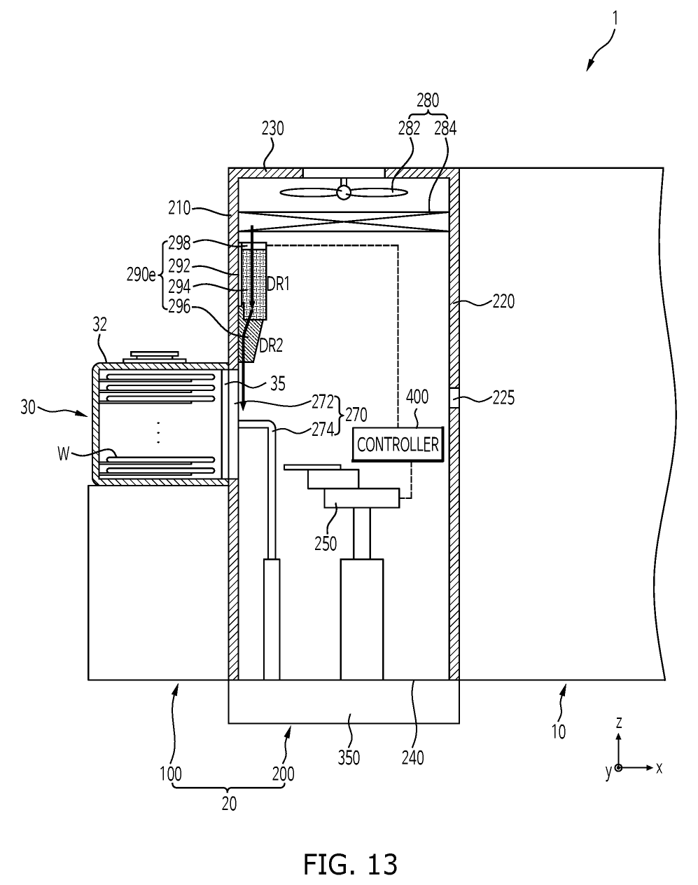

FIGS. 12 and 13 illustrate diagrams showing examples in which one or more fans 298 are disposed in the gas guide 290.

Referring to FIGS. 12 and 13, one or more fans 298 may be placed in the gas guide 290 to increase the speed at which the gas introduced into the gas guide 290 is discharged along the second path DR2.

In an embodiment, the controller 400 may control one or more operations of the one or more fans 298. For example, the controller 400 may operate the one or more fans 298 in response to the container 30 being opened. The controller 400 may execute the process steps of FIG. 4 and thus control the separation of the door 35 and activation of the one or more fans 298. Alternatively, the one or more fans 298 may be operated in response to sensing, by a sensor device or the like, that the door 35 the container 30 is being opened. By operating the one or more fans 298 at the time the container 30 is opened, gas may be blown more strongly only when necessary, without unnecessary fan operation. In an embodiment, the controller 400 may operate the one or more fans 298 during a time when the door 35 is separated from the container 30 or opened. Alternatively, the one or more fans 298 may be operated in response to sensing, by a sensor device or the like, such as a magnetic sensor (e.g., a reed switch), an infrared (IR) sensor, or a limit switch, that the door 35 of the container 30 is being opened.

Referring to FIG. 12, one or more fans 298 may be disposed at the lower part of the gas guide 290 to increase the speed at which gas (e.g., the first portion of the gas) is discharged along the second path DR2 through the discharge portion 296 at the lower part of the gas guide 290.

Referring to FIG. 13, one or more fans 298 may be disposed at the upper part of the gas guide 290 to increase the speed at which the gas is introduced into the gas guide 290 through the first path DR1 via the duct 294.

In another embodiment, the one or more fans 298 may include a fan disposed at the upper part of the gas guide 290 and a fan disposed at the lower part of the gas guide 290.

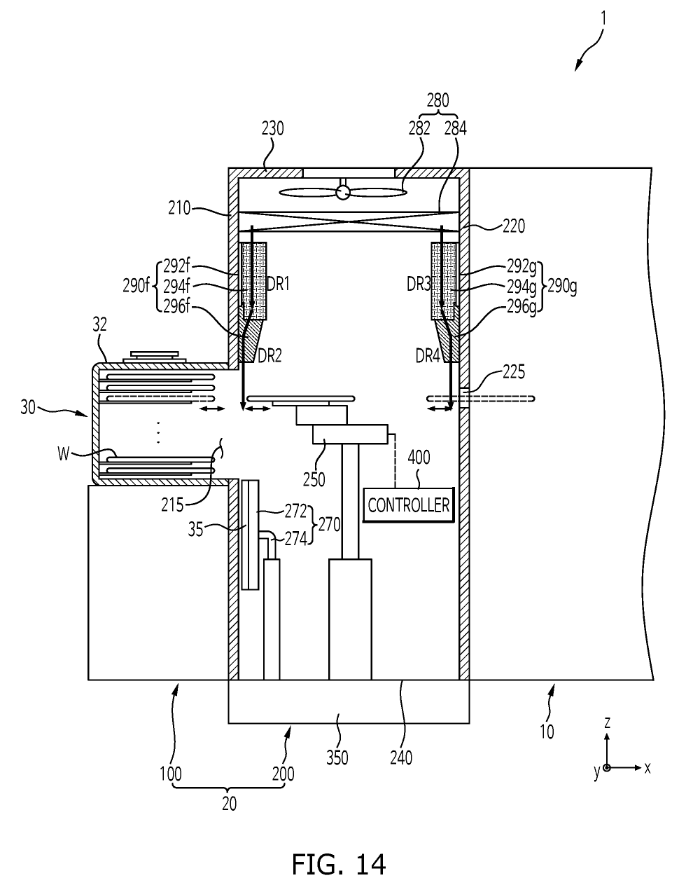

FIGS. 14 through 16 illustrate examples in which a second gas guide is further provided according to various embodiments of the present disclosure. Referring to FIGS. 2, 3, and 7 to 13 described above, the gas guide 290 may correspond to the first gas guide 290f of FIGS. 14 to 16.

Referring to FIGS. 14 to 16, the second gas guide 290g may be disposed to face the front face 210 of the frame and adjacent to the rear face 220 of the frame, which is adjacent to the process facility 10.

A first portion of the gas blown from the blowing fan 282 may flow into the first gas guide 290f through a first path DR1, and a second portion of the gas blown from the blowing fan 282 may flow into the second gas guide 290g through a third path DR3. The second gas guide 290g may discharge the second portion of the gas along a fourth path DR4 that is closer to an opening 225, which is a path through which the substrate W is transferred between the frame 200 and the process facility 10, than the third path DR3. In this way, contamination of the substrate W may be prevented and/or removed when transferring the substrate W to the process facility 10.

The first gas guide 290f may include a first duct 294f into which gas is introduced through the first path DR1, and, at the lower end of the first duct 294f, a first discharge portion 296f connected with the first duct 294f. The first discharge portion 296f may receive and guide gas from the first duct 294f, and discharges it along the second path DR2.

The second gas guide 290g may include a second duct 294g into which gas is introduced through the third path DR3, and a second discharge portion 296g connected to the second duct 294g at a lower end of the second duct 294g. The second discharge portion 296g may receive and guide the second portion of gas from the second duct 294g, and discharge it along the fourth path DR4.

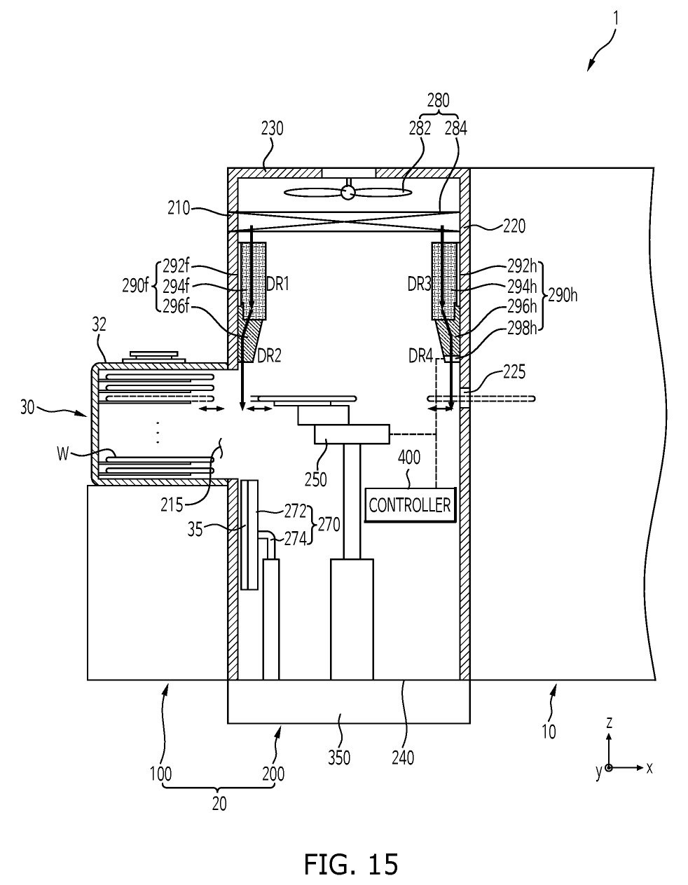

Referring to FIG. 15, one or more fans 298h may be disposed in the second gas guide 290h to increase the speed at which the gas introduced into the second gas guide 290h is discharged along the fourth path DR4.

For example, one or more fans 298h may be disposed at the lower part of the second gas guide 290h so as to increase the speed at which the gas is discharged through the fourth path DR4 from the lower part of the second gas guide 290h. In another example, one or more fans 298hmay be disposed at the upper part of the second gas guide 290h so as to increase the speed at which gas is introduced into the second gas guide 290h through the third path DR3. In yet another example, a plurality of fans may be disposed at both the upper and lower parts of the second gas guide 290h.

The controller 400 may control one or more operations of the one or more fans 298h. For example, the controller 400 may operate the one or more fans 298h in response to the substrate W being transferred to the process facility 10 through the opening 225. For example, a sensor device may detect the substrate W being transferred to the process facility 10 through the opening 225. For example, a sensor device, such as a photoelectric sensor (e.g., a through-beam sensor or light barrier), a capacitive sensor, or a vision sensor, may detect the substrate W being transferred to the process facility 10 through the opening 225. The present disclosure is not limited thereto. In an embodiment, during a time when the door 35 of the container 30 is opened, the controller 400 may activate the one or more fans 298h. Thus, gas may be blown more strongly only when necessary, without unnecessary fan operation.

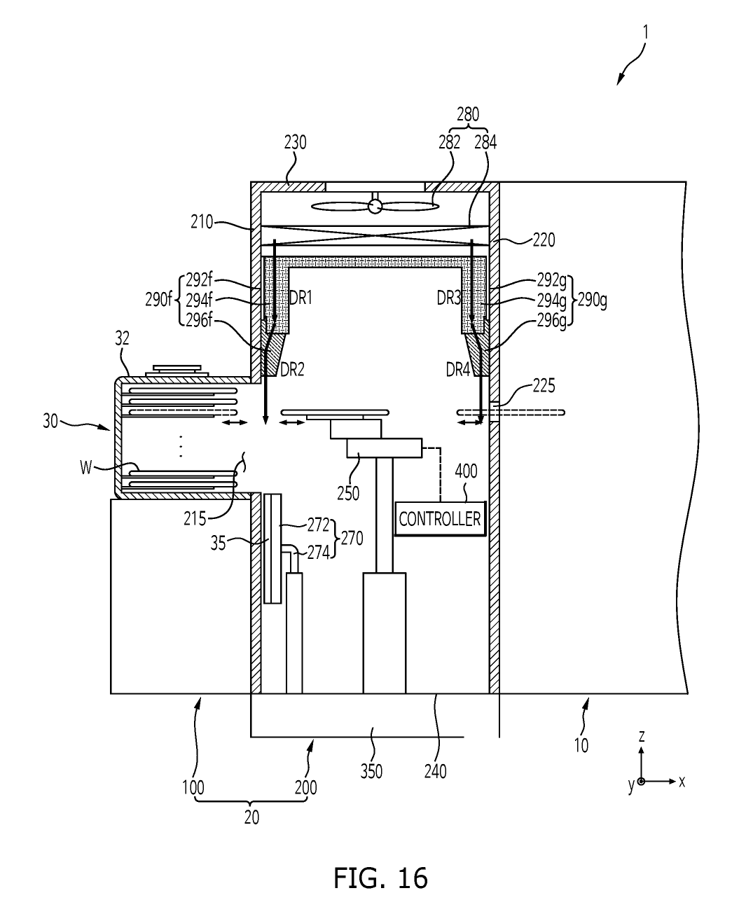

Referring to FIG. 16, the first duct 294f and the second duct 294g may be connected to each other so as to be configured integrally. By integrating the first duct 294fand the second duct 294g, the assembly and installation of the duct structure may be simplified in the manufacturing process. In addition, at the portion where the first duct 294f is connected to the second duct 294g, an extended flow path may be formed so that a greater amount of gas can be introduced or distributed. This may allow a larger flow of gas to enter the first gas guide 290f and the second gas guide 290g, securing a sufficient supply of gas needed to prevent the inflow of outside air or contamination.

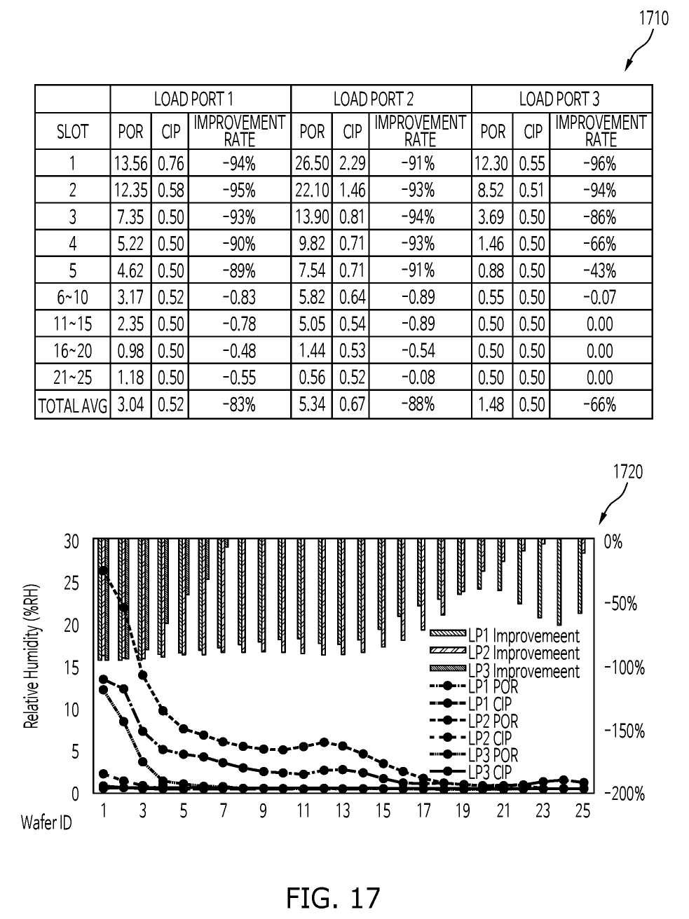

FIG. 17 illustrates data comparing relative humidity inside the container 30, depending on whether the gas guide is installed.

A table 1710 in FIG. 17 shows the measurement of relative humidity according to substrate position (Slot) for each load port, comparing a case without a gas guide (POR) and a case with a gas guide (CIP). When the gas guide is present, the relative humidity decreases significantly compared to when the gas guide is absent, and a large relative humidity improvement rate is confirmed for each of load ports 1, 2, and 3.

A graph 1720 in FIG. 17 is based on the table 1710, plotting a line graph for the relative humidity in the container 30 by substrate ID depending on whether the gas guide is present, and a bar graph for the improvement rate at each load port. On the graph 1720, the POR curve may show a relatively higher relative humidity, while the CIP curve may maintain a lower value. As the substrate ID increases, the POR curve gradually decreases, but the CIP curve shows a low value from the start, suggesting that infiltration of external air or moisture is effectively suppressed. Also, from the improvement-rate bar graph, it may be seen that the relative humidity drops sharply when the gas guide is present, reducing the risk of substrate contamination or moisture absorption.

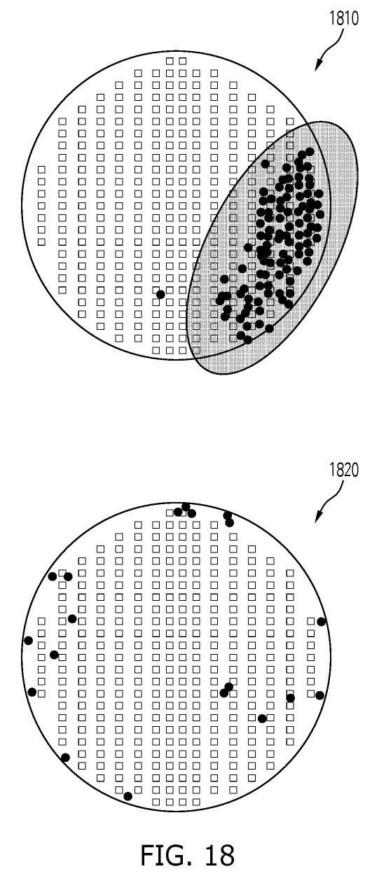

FIG. 18 illustrates the degree of defects on a substrate depending on whether the gas guide is installed.

A first image 1810 shows defective areas on the substrate surface when the process is carried out without installing a gas guide. The more the substrate is exposed to higher-humidity gas, the higher the probability of defects on the substrate surface may become. For example, as the substrate is exposed to higher-humidity gas for longer durations, the likelihood of defects forming on the substrate surface increases. When the container accommodating the substrate is opened, the flow of outside air with increased humidity may easily penetrate the area near the container door, so in the first image 1810, defects may be concentrated in the substrate area near the door.

A second image 1820 shows defective areas on the substrate surface when the same process is performed with the gas guide installed. The gas guide may suppress inflow of outside air into the container accommodating the substrate, thereby reducing any humidity increase near the door. As a result, referring to the second image 1820, moisture condensation on the substrate surface may be alleviated, and the defect frequency may be noticeably decreased. Such an action of the gas guide may reduce the defect rate of the entire production process and contribute to improving the quality and yield of semiconductors.

The present disclosure is not limited to the above-described embodiments and the accompanying drawings, and various substitutions, modifications, and changes may be made by those of ordinary skill in the art within the scope not departing from the technical spirit of the present disclosure, all of which also fall within the scope of the present disclosure.

What is claimed is:

1. A transfer system comprising:
a load port configured to receive a container accommodating a substrate;
an enclosure disposed between the load port and a process equipment that performs a semiconductor device manufacturing process on the substrate, wherein the load port, the enclosure, and the process equipment are arranged in a first direction;
a first fan disposed on an upper wall of the enclosure and configured to generate an airflow inside the enclosure flowing from the first fan toward a lower wall of the enclosure; and
a first airflow guide disposed on a front wall of the enclosure adjacent to the load port and configured to:
direct a first portion of the airflow along a first path, and
change a flow path of the first portion of the airflow directed along the first path to a second path which is closer, in the first direction, to an inner surface of the front wall of the enclosure.

2. The transfer system of claim 1,
wherein the first airflow guide comprises:
a duct having the first path and configured to receive the first portion of the airflow generated from the first fan and direct the first portion of the airflow along the first path; and
a discharge portion having the second path and connected to a lower end of the duct, and
wherein the discharge portion is configured to receive the first portion of the airflow from the duct, direct the first portion of the airflow received from the duct along the second path, and discharge the first portion of the airflow directed along the second path from the first airflow guide.

3. The transfer system of claim 2,
wherein the first airflow guide further comprises:
a bracket coupled to the front wall of the enclosure and configured to support the duct and the discharge portion.

4. The transfer system of claim 2,
wherein the discharge portion has a plurality of discharge slots and a plurality of discharge passages that change the flow path of the first portion of the airflow toward the plurality of discharge slots,
wherein each discharge slot of the plurality of discharge slots extends in a second direction perpendicular to the first direction and parallel to the inner surface of the front wall of the enclosure,
wherein the front wall of the enclosure is adjacent to the load port in the first direction,
wherein the plurality of discharge slots include a plurality of discharge openings which are positioned at a lower surface of the first airflow guide and are open toward the lower wall of the enclosure, and
wherein the first portion of the airflow is discharged along the second path through the plurality of discharge slots from the first airflow guide.

5. The transfer system of claim 4,
wherein the duct has a plurality of inflow slots and a plurality of inflow passages that are connected to the plurality of inflow slots and the plurality of discharge passages, respectively,
wherein each inflow slot of the plurality of inflow slots extends in the second direction,
wherein the plurality of inflow slots include a plurality of inflow openings which are positioned at an upper surface of the first airflow guide and are open toward an upper wall of the enclosure, and
wherein the first portion of the airflow is introduced into an inside of the duct along the first path through the plurality of inflow slots and is delivered to the discharge portion through the plurality of inflow passages.

6. The transfer system of claim 5,
wherein a total area of the plurality of discharge openings, positioned at the lower surface of the first airflow guide, of the plurality of discharge slots is smaller than a total area of the plurality of inflow openings, positioned at the upper surface of the first airflow guide, of the plurality of inflow slots.

7. The transfer system of claim 5,
wherein a discharge slot, closest to a door of the container in the first direction, of the plurality of discharge slots has a largest area among the plurality of discharge slots.

8. The transfer system of claim 1, further comprising:
one or more second fans disposed at the first airflow guide and configured to increase a flowing speed of the first portion of the airflow which is discharged along the second path; and
a controller configured to control an operation of each second fan of the one or more second fans.

9. The transfer system of claim 8,
wherein the controller is configured to operate the one or more second fans during a time when a door of the container is separated from the container.

10. The transfer system of claim 8,
wherein the one or more second fans are disposed at a lower part of the first airflow guide and configured to increase the flowing speed of the first portion of the airflow which is discharged along the second path from the lower part of the first airflow guide.

11. The transfer system of claim 8,
wherein the one or more second fans are disposed at an upper part of the first airflow guide and configured to increase a flowing speed of the first portion of the airflow which is introduced through the first path.

12. The transfer system of claim 1, further comprising:
a second airflow guide disposed on a rear wall of the enclosure adjacent to the process equipment and facing the front wall of then enclosure,
wherein a second portion of the airflow generated from the first fan is introduced into the second airflow guide through a third path, and
wherein the second airflow guide is configured to discharge the second portion of the airflow along a fourth path that is closer, in the first direction, to an inner surface of the rear wall of the enclosure, and
wherein the rear wall includes an opening through which the substrate is transferred between the enclosure and the process equipment, than the third path.

13. The transfer system of claim 12, further comprising:
one or more second fans disposed in the second airflow guide and configured to increase a flowing speed of the second portion of the airflow which is discharged along the third path; and
a controller configured to control an operation of each second fan of the one or more second fans.

14. The transfer system of claim 13,
wherein the controller is configured to operate the one or more second fans in response to detecting the substrate being transferred to the process equipment through the opening.

15. The transfer system of claim 12,
wherein the first airflow guide comprises:
a first duct having the first path and configured to receive the first portion of the airflow generated from the first fan and direct the first portion of the airflow along the first path; and
a first discharge portion having the second path and connected to a lower end of the first duct and configured to receive the first portion of the airflow from the first duct, direct the first portion of the airflow received from the first duct along the second path, and discharge the first portion of the airflow directed along the second path from the first airflow guide,
wherein the second airflow guide comprises:
a second duct having the third path and configured to receive the second portion of the airflow generated from the first fan and direct the second portion of the airflow along the first path; and
a second discharge portion having the fourth path and connected to a lower end of the second duct and configured to receive the second portion of the airflow from the second duct, direct the second portion of the airflow received from the second duct along the fourth path, and discharge the second portion of the airflow directed along the fourth path from the second airflow guide, and
wherein the first duct and the second duct are connected with each other and formed integrally.

16. The transfer system of claim 1, further comprising:
a filter disposed below the first fan and configured to filter contaminants from air introduced into an inside of the enclosure.

17. The transfer system of claim 1, further comprising:
an exhaust portion connected to the lower wall of the enclosure and configured to exhaust air introduced into the enclosure.

18. A transfer system comprising:
a load port on which a container accommodating a substrate is positioned;
an enclosure disposed between the load port and a process equipment that performs a semiconductor device manufacturing process on the substrate, wherein the load port, the enclosure, and the process equipment are arranged in a first direction;
a fan disposed on an upper wall of the enclosure and configured to generate an airflow inside the enclosure flowing from the fan toward a lower wall of the enclosure;
an exhaust portion connected to the lower wall of the enclosure and exhausting the airflow inside the enclosure;
a filter disposed below the fan and configured to filter contaminants from air introduced into an inside of the enclosure; and
a first airflow guide disposed on a front wall of the enclosure adjacent to the load port,
wherein the first airflow guide comprises:
a bracket coupled to the front wall of the enclosure;
a duct coupled to the bracket, extending in a second direction perpendicular to the first direction and parallel to an inner surface of the front wall of the enclosure, the duct having a plurality of inflow slots opened toward the upper wall of the enclosure, through which a first portion of the airflow generated from the fan is introduced along a first path, and a plurality of inflow passages configured to deliver the first portion of the airflow; and
a discharge portion coupled to the bracket and connected to a lower end of the duct, the discharge portion receiving the first portion of the airflow from the plurality of inflow passages via a plurality of discharge passages, changing a flow direction of the first portion of gas, and extending in the second direction, the discharge portion having a plurality of discharge slots opened toward the lower wall of the enclosure so as to discharge the first portion of the airflow along a second path directed more toward a door of the container than the first path in the first direction.

19. A semiconductor device manufacturing apparatus comprising:
a load port on which a container accommodating a substrate is positioned;
a process equipment configured to perform a semiconductor device manufacturing process on the substrate;
an enclosure disposed between the load port and the process equipment;
a transfer robot installed inside the enclosure and configured to transfer the substrate between the load port and the process equipment;
a controller configured to control the transfer robot;
a fan disposed on an upper wall of the enclosure and configured to generate an airflow flowing from the fan toward a lower wall of the enclosure; and
an airflow guide disposed on a front wall of the enclosure adjacent to the load port,
wherein a portion of the airflow generated from the fan is introduced into the airflow guide through a first path, and
wherein the airflow guide is configured to discharge the portion of the airflow along a second path directed more toward a door of the container than the first path.

20. The semiconductor device manufacturing apparatus of claim 19,
wherein the controller is configured to control the transfer robot to transfer the substrate accommodated in the container to the process equipment,
wherein the process equipment is configured to perform the semiconductor device manufacturing process on the transferred substrate, and
wherein the controller is configured to control the transfer robot to transfer the substrate, on which the semiconductor device manufacturing process is completed, from the process equipment to the container.
